(19) United States
(12) Patent Application Publication
(10) Pub. No.: US 2024/0110573 A1
(43) Pub. Date: Apr. 4, 2024

(54) VEHICLE ASSEMBLY COMPRISING A PRESSURE EQUALIZATION ELEMENT

(71) Applicant: Schwäbische Hüttenwerke Automotive GmbH, Aalen (DE)

(72) Inventor: Uwe Meinig, Bad Saulgau (DE)

(21) Appl. No.: 18/140,139

(22) Filed: Apr. 27, 2023

(30) Foreign Application Priority Data
May 2, 2022 (DE) 10 2022 110 763.9

(51) Int. Cl. F04D 25/06; F04D 29/40; H02K 5/10; H02K 7/14

(52) U.S. Cl. CPC F04D 25/06; F04D 29/406; H02K 5/10; H02K 7/14

(57) ABSTRACT

A vehicle assembly including: a housing including a housing enclosure structure which exhibits a housing opening; an electrical component part accommodated in the housing; an electrical connector including an outer connector contact, for electrically connecting to an electrical system of a vehicle, and an inner connector contact; a component part contact which is connected in an electrically conductive way to the electrical component part and connected to the inner connector contact in a connecting region; a closure body for closing the housing opening against the ingression of liquid; and a gas-permeable pressure equalization element which is a constituent part of the closure body, in order to enable pressure to be equalized with the environment of the housing via the closure body, wherein the housing opening, when it is not closed, enables the connecting region to be accessed.

### CROSS REFERENCE TO RELATED APPLICATION

This application claims benefit of priority from German Patent Application No. 10 2022 110 763.9, filed May 2, 2022. The contents of this application are incorporated herein by reference.

### FIELD OF THE INVENTION

The invention relates to a vehicle assembly, such as for example an electrically driven pump, and to a method for fitting the vehicle assembly, wherein the vehicle assembly exhibits a housing featuring a housing opening which is closed in an at least substantially liquid-tight seal by means of a gas-permeable pressure equalization element. More specifically, the invention relates to the arrangement of the housing opening relative to a connecting region for an electrical component part of the vehicle assembly.

### BACKGROUND OF THE INVENTION

Due to temperature fluctuations and fluctuations in ambient pressure such as occur when driving uphill or downhill, there is a risk of water and dirt entering the housings of electrical and/or electronic component parts used in motor vehicles, including electromechanical component parts, and causing malfunctions and/or faults. For this reason, vehicle assemblies comprising electrical component parts often use pressure equalization elements, in most cases in the form of pressure equalization membranes, which equalize differences in pressure between the interior space of the housing and the external environment. On the one hand, these pressure equalization elements enable pressure to be equalized, but on the other hand, they prevent dirt particles or liquid media such as for example water or oil from penetrating into the housing interior. Self-adhesive, welded or otherwise mechanically fastened pressure equalization elements made of PTFE, ePTFE or nylon fleece are used inter alia as pressure equalization elements and/or filter media. An extensive strength of seal against the ingression of liquid is typically achieved by choosing a hydrophobic and/or oleophobic material as the filter material and/or membrane material.

DE 10 2004 056 662 A1 and DE 10 2008 001 594 A1, for example, which are incorporated herein by reference, disclose arranging a pressure equalization membrane on a housing cover which caps an interior space of the housing in which electrical component parts of the respective vehicle assembly are accommodated. Since the pressure equalization element is directly fastened to a large structure, i.e. the housing cover, incorrectly fitting the pressure equalization element means that the entire housing cover, i.e. a large, complex and correspondingly expensive component part, has to be rejected as being faulty. The usual strength-of-seal test on the housing in series production is also made more difficult, because when the pressure burden source and/or partial vacuum source is docked in order to determine the leak rates, the pressure equalization element makes it more difficult to quickly equalize the pressure between the docked pressure source and the interior space of the housing, as is required for short testing times. If the housing cover exhibits an electrical connector for the electrical connection between the vehicle assembly and an electrical system of the vehicle, then electrically connecting the electrical component part while fitting the housing cover presents an additional problem. The electrical component part has to be electrically connected to the electrical connector either before fitting the housing cover or automatically while fitting the housing cover. One solution which is favorable with respect to fitting is to connect it by means of a press-fit connection. Conversely, press-fit connections can prove problematic with regard to the quality of the electrical connection.

### SUMMARY OF THE INVENTION

An aspect of the invention aims to enable an electrical component part to be electrically connected in a simple and reliable way in a vehicle assembly which comprises a housing featuring a pressure equalization element and in which the electrical component part is accommodated.

Another aspect can be to simplify the strength-of-seal test on the housing and in particular to shorten the testing time required for this.

An aspect of the invention is based on a vehicle assembly which comprises a housing and an electrical and/or electronic and/or electromechanical component part accommodated in the housing, such as for example an electric motor and/or an electronic controller and/or one or more sensors. Component parts of this type and their parts are referred to in the following as an “electrical component part”. The vehicle assembly also exhibits an electrical connector comprising: an outer connector contact for electrically connecting the vehicle assembly to an electrical system of a vehicle; and an inner connector contact. The electrical component part is connected in an electrically conductive way to a component part contact which is joined, for example soldered, welded and/or clamped, in an electrically conductive way to the inner connector contact of the electrical connector in a connecting region.

The housing comprises a housing enclosure structure which delineates an interior space of the housing circumferentially and/or on an end-facing side and is provided with a housing opening. The housing enclosure structure forms the housing of the vehicle assembly together with one or more other housing structures and can be fitted as a structural unit in order to form the housing. The vehicle assembly has a closure body for closing the housing opening against the ingression of liquid. The closure body comprises a gas-permeable pressure equalization element which is at least substantially liquid-tight but which, when the closure body is fitted, enables pressure to be equalized with the external environment of the housing via the housing opening and the closure body. Although the pressure equalization element can in principle form the closure body as a whole if correspondingly designed, it is preferable to this for the closure body to comprise a gas-tight and liquid-tight support body and for the pressure equalization element to be joined to the support body in a liquid-tight seal, preferably a gas-tight seal, for example by welding or gluing.

In accordance with an aspect of the invention, the position and size of the housing opening allows the connecting region to be accessed by a tool, for example a joining tool or a testing and/or diagnostic tool, and/or visually inspected when the housing opening is not closed, i.e. before the closure body is affixed. The housing enclosure structure which is provided with the housing opening can therefore be joined to the one or more other enclosure structures to form the housing of the vehicle assembly even before the closure body is fitted, such that it is then merely necessary to fit the closure body for closing the housing opening in order to complete the housing.

In first embodiments, the connecting region is located in the interior space of the housing delineated by the housing enclosure structure and is accessible for a tool and/or visual inspection, before the closure body is attached, via the housing opening which is then still open. In second embodiments, the component part contact and the inner connector contact to be connected to it protrude outwards into or through the housing opening, such that at least some of the connecting region is situated outside the interior space of the housing. In the second embodiments, the closure body forms a cap which, when fitted, closes the housing opening and protectively surrounds the connected contacts over their length which protrudes out of the housing opening.

If the pressure equalization element is not joined directly to the comparatively large housing enclosure structure, which at least partially surrounds or at least predominantly covers the interior space of the housing, but is rather a constituent part of a closure body which is smaller than the housing enclosure structure, the leakage test in series production can be performed easily and within a short period of time via the housing opening, and the housing opening can then be closed using the closure body. Aside from the housing opening which is not yet closed, the strength of seal on the housing can be checked. The vehicle assembly or at least the housing can already be fitted as completely as possible, such that a reliable leakage test, for example in the form of a pressure drop test, is possible at a short cycle time, without a pressure equalization element complicating, delaying or even distorting the leakage test. Due to their arrangement relative to the connecting region, the inner connector contact does not have to already be connected in an electrically conductive way to the component part contact before the housing is assembled. A press-fit connection or plugging connection is also not required, although such a connection is not to be ruled out from the outset. Due to the improved accessibility, the inner connector contact and the component part contact can be reliably connected to each other in an electrically conductive way after the housing enclosure structure has been fitted. Proven connecting techniques such as soldering or welding can in particular be used.

The closure body can be formed in the manner of a cover and can cap the connecting region. It can be at least substantially disc-shaped in order to cover the housing opening on its end-facing side only. It can however also be cap-shaped or cup-shaped in order to cover the housing opening and circumferentially surround any contacts which optionally protrude outwards beyond the housing opening. The closure body is advantageously seated on the housing enclosure structure in the region of the housing opening.

The housing opening can be provided in or on a circumferential wall of the housing enclosure structure. The housing opening can extend completely in the region of the circumferential wall. In one modification, it can extend from the circumferential wall into an end-facing wall of the housing enclosure structure. A housing opening which extends completely or only partially in or on a circumferential wall of the housing enclosure structure is for example suitable in embodiments in which the inner connector contact protrudes from an end-facing wall of the housing enclosure structure into the interior space of the housing. Preferably, however, the housing opening is provided in an end-facing wall of the housing enclosure structure and circumferentially surrounded by an end-facing wall area of the housing enclosure structure.

It is advantageous for the housing opening to be significantly smaller than the housing enclosure structure, i.e. significantly smaller than the end-facing wall area and/or circumferential wall area of the housing enclosure structure. If the housing opening is provided on an end-facing side of the housing enclosure structure, the housing enclosure structure as viewed in a plan view onto the housing opening can as a whole exhibit an end-facing wall area which is more than twice or more than three times or more than four times as large as the housing opening. If the housing opening is provided on the circumference of the housing enclosure structure, the housing enclosure structure as viewed in a plan view onto the housing opening, i.e. in a side view of the housing enclosure structure, can exhibit a circumferential wall area projected parallel to the direction of view which is more than twice or more than three times or more than four times as large as the housing opening.

In preferred embodiments, the housing opening and the connecting region are aligned. For the purposes of an aspect of the invention, the housing opening and the connecting region are aligned when a straight line can be drawn through the housing opening, starting from the connecting region. If the housing opening and the connecting region are jointly aligned in this sense, the connecting region can be reached by a tool along a straight path, wherein the tool may have to be held obliquely with respect to the housing opening. It is equally possible to visually inspect the connecting region through the housing opening. The tool can for example be a testing tool or in particular a joining tool. In preferred embodiments, a joining tool can be guided through the housing opening which has not yet been closed into the interior space of the housing delineated by the housing enclosure structure and up to the contact region, and the internal connector contact and the component part contact can be joined in an electrically conductive way.

It is particularly favorable for the housing opening as viewed in a plan view to overlap at least predominantly with the connecting region over an area. In such embodiments, the housing opening and the at least predominant planar region of the connecting region are orthogonally aligned with the housing opening. The orthogonal alignment extends through the housing opening and the connecting region and can extend in parallel, in particular parallel to a normal of a cross-section of the housing opening. If the cross-section of the housing opening varies from the outside to the inside, the orthogonal alignment can in particular extend parallel to the normal of a minimum cross-section. If the connecting region is situated in the interior space of the housing, it is advantageous for the area of the connecting region to be at least predominantly visible through the housing opening as viewed in an orthogonal plan view onto the housing opening. A connecting region of the inner connector contact and component part contact which is situated in the interior space of the housing is visible when at least one of these two contacts is visible through the housing opening.

If, when the housing opening and the connecting region are aligned, their alignment does not extend orthogonally onto the housing opening but rather at an inclination obliquely with respect to an alignment pointing orthogonally with respect to a cross-section of the housing opening, the alignment between the housing opening and the connecting region preferably points at an angle of inclination of at most 50° or at most 40° to the orthogonal alignment.

The vehicle assembly can exhibit multiple component part contacts which are connected in an electrically conductive way to the electrical component part or to another electrical component part which is optionally accommodated in the housing. The connector can correspondingly exhibit multiple electrically conductive outer connector contacts, each for connecting to the electrical system of the vehicle, and multiple electrically conductive inner connector contacts which are each joined in an electrically conductive way to one of the component part contacts in the connecting region. The size and arrangement of the housing opening are advantageously designed such that when the housing opening is not closed, it enables multiple pairs of the inner connector contacts and component part contacts and preferably all of the pairs of the inner connector contacts and component part contacts to be accessed.

If the one or more additional connector contacts and component part contacts are arranged in the interior space of the housing, they can be accessed through the housing opening which is still open. When the housing opening is not closed, the respective component part contact and the respective inner connector contact can therefore be joined in an electrically conductive way by means of a joining tool which protrudes through the housing opening, and/or the electrical connection between the respective component part contact and the inner connector contact can be tested by means of a testing tool or visually. In such first embodiments, all the component part contacts and/or all the inner connector contacts are preferably visible as viewed in a plan view onto the housing opening when the housing opening is not closed.

In the alternative second embodiments, the component part contacts and corresponding inner connector contacts protrude into or through the housing opening and accordingly are particularly easy to access. This expediently applies to all the component part contacts of the vehicle assembly, such as can be connected to the electrical system of the vehicle via the electrical connector.

Mixed forms are also conceivable, in which at least one of the component part contacts and at least one of the inner connector contacts are connected in the interior space of the housing and at least one other of the component part contacts and at least one other of the inner connector contacts are connected on the outside, in or in front of the housing opening. Dividing the connecting region in this way can however lead to impairment of accessibility to the part of the connecting region located in the interior space of the housing.

The statements made with respect to the alignment of a single pair of contacts apply similarly to each of the one or more other component part contacts and inner connector contacts.

The housing can comprise a single-part or multiple-part housing support structure, which mounts the electrical component part, and a housing cover which is joined to the housing support structure. The housing support structure and the housing cover can jointly surround said interior space of the housing. The electrical component part can be accommodated in this interior space of the housing. Alternatively or additionally, the connecting region can be formed in the interior space of the housing. The housing cover can be the housing enclosure structure which in accordance with an aspect of the invention is provided with the housing opening which serves to equalize pressure and enables access.

In one development, the vehicle assembly comprises an electric motor and an electronic controller for the electric motor. The electrical component part can form the electric motor or the electronic controller or a part of the electronic controller. In such embodiments, the housing can comprise a motor housing featuring a motor space for the electric motor, a motor space cover and an electronics space cover. The electrical component part and/or the connecting region is/are accommodated in an electronics space which forms the interior space of the housing described above. The motor space cover separates the motor space from the electronics space on an end-facing side. The electronics space cover delineates the electronics space on the end-facing side facing away from the motor space cover and forms the housing enclosure structure provided with the housing opening. Preferably, the electronics space cover closes the electronics space in a liquid-tight seal and, aside from the required pressure equalization via the pressure equalization element, also broadly in a gas-tight seal. The electronics space cover can be joined to the motor housing or preferably directly to the motor space cover only.

The connector can comprise a connector housing and an electric& connecting line which extends through the connector housing and forms the outer connector contact and the inner connector contact. The connector housing and the housing enclosure structure can form a structural unit and can in particular be fitted as a unit on one or more other housing structures of the housing, wherein the connector housing can protrude from the housing enclosure structure in a direction which is normal with respect to an end-facing side of the housing enclosure structure or preferably in a radial and/or tangential direction. The connector housing can be formed in one piece with the housing enclosure structure, for example in a casting process. The housing enclosure structure and the connector housing are expediently formed separately and joined to each other to form a fitted unit.

The outer connector contact can form an outer end of the connecting line. The connecting line can extend further into the interior space of the housing, beyond the inner connector contact. Preferably, however, the inner connector contact forms one end of the electrical connecting line. The connector housing can hold the connecting line and position it relative to the component part contact, such that the inner connector contact is located opposite the component part contact at a small distance or is already in abutting contact with the component part contact. The connector housing advantageously holds the connecting line such that fitting the housing enclosure structure simultaneously also positions the inner connector contact relative to the component part contact directly in a joining position for connecting and no other fitting step is required before joining the contacts. The connector housing can advantageously position the connecting line such that the inner connector contact and the housing opening are aligned, wherein the alignment preferably points normally with respect to the housing opening but can in principle also point obliquely with respect to the housing opening.

The electrical connector is preferably a plugging connector, wherein the outer connector contact can be a female or a male plugging contact element.

In preferred embodiments, the electrical connector exhibits a connector port on a free end-facing side for connecting to the electrical system of a vehicle. The connecting line extends up to this free end-facing side, where it terminates at the outer connector contact, which is a constituent part of the connector port. The housing enclosure structure can exhibit the housing opening in an alignment which points normally and/or orthogonally with respect to the connector port. If the connector is a plugging connector, the housing opening is situated in an extension of the connector as viewed from the connector port in the plugging direction in such embodiments.

If the vehicle assembly can be connected to the electrical system of the vehicle on an end-facing side of the electrical connector, an axis which is central with respect to the connector and extends orthogonally with respect to the end-facing side of the connector preferably intersects the housing opening as viewed in a plan view onto the housing opening, and the housing opening is arranged close to the connector as viewed in the plan view onto the housing opening, in a half of the housing enclosure structure into which the inner connector contact protrudes. The housing opening preferably extends completely in this half of the housing enclosure structure. The closer the housing opening is to the connector, the shorter the length by which the inner connector contact protrudes into the interior space of the housing can be. This is beneficial to positioning the inner connector contact and to connecting the component part contact and connector contact.

With regard to the required strength of seal on the housing and in order to attach the closure body easily, it is advantageous for the housing opening to be smaller than the housing enclosure structure. Since the connecting region is conversely to be easily accessible, the housing opening can be directly adjacent to the connector.

In typical embodiments, the connector comprises multiple electrical connecting lines which each extend through the connector housing and each form an outer connector contact and an inner connector contact. The statements made with respect to a single connecting line and the connector contacts of this connecting line also apply to each of the other connecting lines of the electrical connector.

In advantageous embodiments, the closure body comprises a passage and a gasket structure which surrounds the passage in a plan view onto the passage. The pressure equalization element closes the passage in a liquid-tight seal. The pressure equalization element can in particular be arranged on an inner side of the closure body facing the connecting region. The gasket structure is designed to circumferentially close the housing opening in a liquid-tight and preferably gas-tight seal, either by co-operating directly with the housing enclosure structure or by means of an additional gasket element.

The passage advantageously exhibits a cross-section which is significantly smaller than the housing opening. The housing opening can thus be more than twice or more than three times or more than four times as large as the cross-section of the passage. If the cross-section of the passage varies in the direction of flow, this applies to the smallest cross-section.

With respect to the inflow direction into the interior space of the housing, the closure body can comprise impact protection means for inflowing particles upstream of the pressure equalization element in or even in front of the passage.

In first variants of the closure body, the gasket structure can simultaneously form a joining structure, by joining the closure body along the gasket structure to the housing enclosure structure in a liquid-tight and broadly gas-tight seal, wherein the gasket structure advantageously also surrounds the housing opening in a plan view onto the passage of the closure body. Alternatively or additionally, it can however in principle also be joined to the housing enclosure structure in the housing opening.

The closure body can be joined to the housing enclosure structure in a material bond along a joining area or line, in a liquid-tight and preferably gas-tight seal, circumferentially around and/or in the housing opening. This applies in particular to the first variants of the closure body. The closure body is preferably joined to the housing enclosure structure by welding, for example ultrasonic welding or laser welding or friction welding. In order to facilitate friction welding, the gasket structure (if it simultaneously serves as a joining structure) can be rotationally symmetrical with respect to an axis pointing normally and/or orthogonally with respect to the housing opening.

The closure body can comprise a support body through which the passage extends and to which the pressure equalization element is joined around the passage in an at least liquid-tight and preferably gas-tight seal, for example by welding, gluing, clamping and/or pressing. The gasket structure and/or the impact protection means (if provided) can be formed on the support body. The support body is preferably formed in one piece in an original-molding process, for example from plastic, preferably a thermoplastic.

In the first variants, the closure body can consist solely of the support body and the pressure equalization element joined to it. In second variants, the closure body can additionally comprise a gasket arranged on the support body in the region of the gasket structure, such as for example a gasket element which is releasably held by means of the gasket structure. In the second variants, a joining structure is provided in addition to the gasket structure. It can be formed on the support body, for example in the form of a joining flange which is circumferential in a plan view or in the form of multiple joining flanges which each protrude in the shape of a vane. The joining structure can be designed to affix the closure body, for example in a screw connection or locking connection.

For the purposes of a leakage test, the housing enclosure structure can exhibit a free docking area of the housing, circumferentially around the housing opening in a plan view onto it, for a circumferentially gas-tight contact with a testing probe for testing the strength of seal on the housing. Within the framework of this test, a leak rate of the housing can be determined and for example compared with a predetermined maximum permissible leak rate. For the purposes of testing, a pressure burden or a partial vacuum or a pressure burden and then a partial vacuum is applied to the housing by means of the testing probe via the housing opening which is not yet closed.

In order to facilitate a leakage test on the joining connection between the closure body and the housing enclosure structure, the housing enclosure structure can exhibit a free docking area of the housing and the closure body can exhibit a free docking area of the closure body, each intended for a circumferentially gas-tight contact with the same testing probe, in a plan view onto the closure body. In the plan view, the docking area of the closure body encircles the passage of the closure body within the joining connection. In the same plan view, the docking area of the housing encircles the closure body, i.e. also surrounds the docking area of the closure body. The docking area of the housing described above can also have a second function of forming the docking area of the housing for the leakage test on the joining connection.

The docking area of the housing and the docking area of the closure body can be planar, parallel end-facing areas which preferably extend next to and level with each other in a shared docking plane.

The housing enclosure structure can exhibit a raised docking ring comprising the docking area of the housing as an end-facing area, circumferentially around the housing opening. Alternatively, the housing opening can be arranged in a recess of the housing enclosure structure, and the docking area of the housing can encircle the recess. Both embodiments enable the docking area of the housing to be arranged level with the optional docking area of the closure body.

The vehicle assembly can in particular be an auxiliary assembly, such as for example a compressor, a fan or preferably a pump for coolant, lubricating oil or transmission oil. A preferred example is a pump-motor unit or compressor-motor unit, each comprising an impeller for delivering fluid, an electric motor for rotationally driving the impeller and an electronic controller for the electric motor, wherein the impeller, the electric motor and the controller are arranged in the housing. The electric motor comprises a stator and a rotor which can be rotated about an axis of rotation. The impeller is advantageously rotatable about the same axis of rotation as the rotor and/or non-rotationally connected to the rotor.

An aspect of the invention does not however relate to electromechanical vehicle assemblies only. Purely electrical and/or electronic vehicle assemblies, such as an electronic motor controller or a diagnostic device, can also form the vehicle assembly in accordance with an aspect of the invention.

An aspect of the invention relates not only to a vehicle assembly but also to a method for fitting a vehicle assembly, preferably the vehicle assembly disclosed herein, wherein the vehicle assembly comprises:
a housing comprising a housing enclosure structure which delineates an interior space of the housing circumferentially and/or on an end-facing side and exhibits a housing opening;
an electrical component part accommodated in the housing, for example an electric motor and/or an electronic controller;
an electrical connector comprising an outer connector contact, for electrically connecting the vehicle assembly to an electrical system of a vehicle, and an inner connector contact;
a component part contact which is connected in an electrically conductive way to the electrical component part and which is adjacent to the inner connector contact in a connecting region;
a closure body for closing the housing opening against the ingression of liquid; and
a gas-permeable pressure equalization element which is a constituent part of the closure body, in order to enable pressure to be equalized with the environment of the housing via the closure body.

Except for the closure body, the vehicle assembly is already assembled at least to this extent and preferably in its entirety, but the housing opening is still open. Before the housing opening is closed, the inner connector contact is joined in an electrically conductive way to the component part contact by means of a joining tool. The joining step can involve joining and thus connecting one or more other component part contact(s) and connector contact(s). Immediately after the joining step or optionally only after one or more other subsequent fitting steps, the housing opening is closed in a liquid-tight seal, but remaining gas-permeable via the pressure equalization element, by the closure body.

If the connecting region is formed in the interior space of the housing, the joining tool for joining the contacts is guided to the connecting region through the housing opening which is still open, and the mutually corresponding contacts are joined in an electrically conductive way in the interior space of the housing. If the contacts protrude outwards through the housing opening, they can be connected in a particularly easy way on the outside, in front of the housing opening. The housing opening can then be closed by a cap-shaped closure body which covers the contacts on the end-facing side and surrounds them circumferentially. Lastly, it is also conceivable for the contacts to extend up to and into the housing opening without protruding beyond the housing opening and to be joined in an electrically conductive way to each other in the housing opening rather than in the interior space of the housing.

In an assembly step preceding the step of joining the contacts, the housing enclosure structure provided with the housing opening, which preferably also exhibits the connector, is joined to a housing support structure which mounts the electrical component part, such that the inner connector contact is directly adjacent to the component part contact in the connecting region and can be connected in the joining step.

### BRIEF DESCRIPTION OF THE DRAWINGS

Example embodiments of the invention are described below on the basis of figures. Features disclosed by the example embodiments, each individually and in any combination of features, advantageously develop the subject matter of the claims and the embodiments described above. There is shown:

FIG. 1 a vehicle assembly comprising a housing which exhibits a housing enclosure structure and a gas-permeable closure body of a first example embodiment;

FIG. 2 an isometric view of a sub-region of the vehicle assembly comprising the housing enclosure structure and the closure body, which is only partially shown, and a housing opening which is thus partially exposed;

FIG. 3 an isometric view of the closure body;

FIG. 4 an enlargement of the partially exposed housing opening, with the closure body of FIG. 2 only partially shown;

FIG. 5 the housing enclosure structure when fitted, in a longitudinal section containing the housing opening and the closure body;

FIG. 6 the housing enclosure structure before the closure body is fitted, in a plan view onto the housing opening which is still open;

FIG. 7 an isometric view of a vehicle assembly comprising a housing enclosure structure featuring a housing opening of a second example embodiment which is still open;

FIG. 8 a sub-region of the vehicle assembly, with the housing enclosure structure and closure body of the second example embodiment fitted;

FIG. 9 a sectional isometric view of the closure body of the second example embodiment;

FIG. 10 a sectional isometric view of a sub-region of the vehicle assembly, with the housing enclosure structure of the second example embodiment fitted;

FIG. 11 a detailed representation of the housing opening, which is closed by the closure body of the second example embodiment, and a testing probe for a leakage test;

FIG. 12 the representation of FIG. 10, with the testing probe docked;

FIG. 13 a vehicle assembly, with a housing enclosure structure and closure body of a third example embodiment fitted;

FIG. 14 a sectional isometric view of the closure body of the third example embodiment;

FIG. 15 a longitudinal section of the housing enclosure structure and closure body of the third example embodiment when fitted;

FIG. 16 a vehicle assembly, with a housing enclosure structure and closure body of a fourth example embodiment fitted;

FIG. 17 a sectional isometric view of the closure body of the fourth example embodiment;

FIG. 18 a longitudinal section of the housing enclosure structure of the fourth example embodiment when fitted and of a modified closure body before it is fitted;

FIG. 19 a longitudinal section of a vehicle assembly comprising a housing enclosure structure of a fifth example embodiment and the closure body of the first example embodiment; and

FIG. 20 a vehicle assembly, with a housing enclosure structure and closure body of a sixth example embodiment fitted.

### DETAILED DESCRIPTION OF THE INVENTION

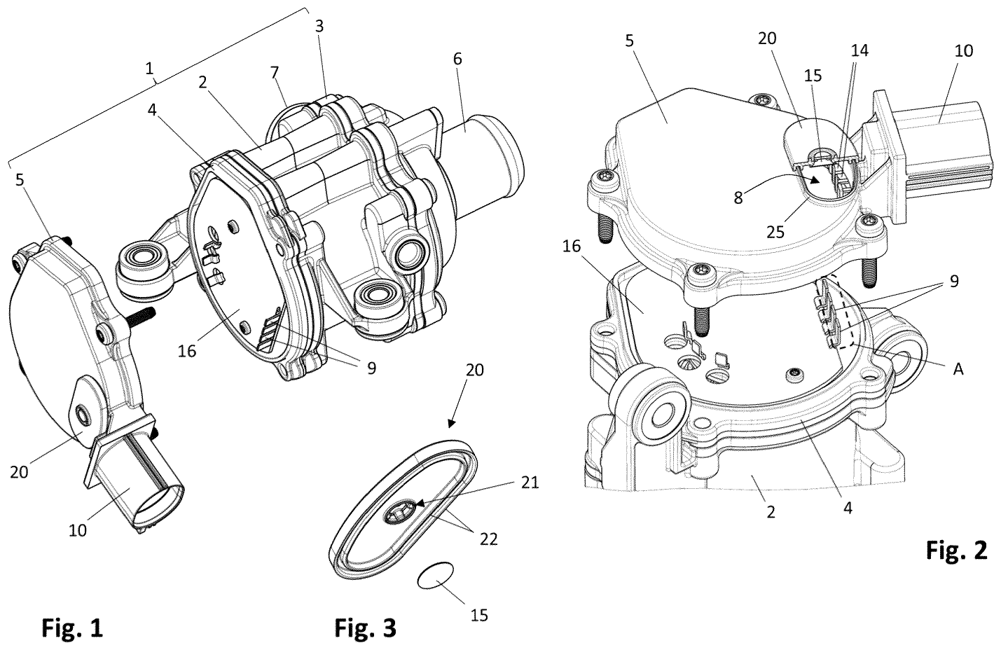

FIG. 1 shows an isometric view of a vehicle assembly. The vehicle assembly is a so-called auxiliary unit, such as for example a transmission oil pump, a fan, a compressor or in particular a coolant pump. The vehicle assembly exhibits a housing 1 in which component parts of the vehicle assembly which can and/or cannot be moved are accommodated. If the vehicle assembly is one of the auxiliary units mentioned by way of example, such as a coolant pump, the vehicle assembly comprises mechanical and electrical components, such as for example an impeller for delivering a fluid, an electric motor for rotationally driving the impeller, and an electronic controller for the electric motor, which can be jointly accommodated in the housing 1. This is the case in the example embodiment.

The housing 1 comprises a motor housing 2 which surrounds a motor space in which the electric motor is accommodated, and a pump space cover 3 which is joined to the motor housing 2 on an end-facing side of the motor housing 2 and which together with the motor housing 2 delineates a pump space in which the impeller of the pump is arranged. The housing 1 comprises an inlet 6 and an outlet 7 for the fluid to be delivered (a coolant in the example embodiment). The inlet 6 and the outlet 7 are structural constituent parts of the pump space cover 3, which can in particular be formed in one piece including the inlet 6 and the outlet 7. The housing 1 also comprises a motor space cover 4 which delineates the motor space on the end-facing side which is located axially opposite the pump space cover 3. The motor space cover 4 serves as a support for an electronic controller for the electric motor. The electronic controller itself and/or its constituent parts are not shown. All that is shown are multiple component part contacts 9 and a circuit board 16 for arranging the electronic component parts of the controller. The component part contacts 9 serve to electrically connect the electric motor and the controller. All the component part contacts 9 are arranged closely adjacent in a shared connecting region and protrude axially from the circuit board 16 in the connecting region.

The housing 1 also comprises a housing enclosure structure 5 which in the example embodiment forms an electronics space cover. In FIG. 1, the electronics space cover 5 and/or housing enclosure structure 5 is raised from the rest of the housing in order to reveal the circuit board 16 and the protruding component part contacts 9. Proceeding from FIG. 1, the housing enclosure structure 5 is placed onto the motor space cover 4 in the axial direction and joined to it in a seal (by means of a circumferential gasket and a screw connection in the example embodiment). Once joined, the motor space cover 4 and the housing enclosure structure 5 enclose the electronics space in a liquid-tight and broadly gas-tight seal, wherein the motor space cover 4 separates the electronics space from the motor space.

FIG. 2 shows the housing region comprising the motor space cover 4 and the housing enclosure structure 5, which in FIG. 2 is also shown raised. The circuit board 16 and the component part contacts 9 are again shown. The component part contacts 9 are arranged in the connecting region A which is indicated in the form of a dashed line and is formed by the component part contacts 9 and the region immediately proximate to them.

Once the housing 1 is fully fitted, the electronics space is closed in a liquid-tight and broadly gas-tight seal, as already mentioned. In order to still be able to equalize differences in pressure between the electronics space and the external environment of the housing 1, the housing enclosure structure 5 exhibits a local housing opening 8 which is closed in a liquid-tight but gas-permeable seal by a closure body 20 when the housing 1 is fully fitted. FIGS. 1 and 2 show the raised housing enclosure structure 5 comprising the fitted closure body 20, wherein the closure body 20 is shown completely in FIG. 1, but only half of it is shown in FIG. 2. The half of the housing opening 8 which is not closed can therefore be seen in FIG. 2.

The vehicle assembly comprises an electrical connector 10 for connecting to an electrical system of a vehicle. The connector 10 can in particular be an electrical plugging connector which can be connected to the electrical system of the vehicle by means of an electrically conductive plugging connection. The connector 10 is a structural constituent part of the housing enclosure structure 5 and can be formed in one piece with it or can be formed separately and then fixedly joined to the cover region of the housing enclosure structure 5 in a seal.

In FIG. 2, inner connector contacts 14 of the connector 10 can be seen through the half-open housing opening 8. The inner connector contacts 14 are joined in an electrically conductive way to the component part contacts 9 when fitted. When joined, the connecting region A directly comprises both the component part contacts 9 and the inner connector contacts 14.

FIGS. 1 and 2 show the fully fitted housing 1 comprising the housing enclosure structure 5 which is raised. The fitting sequence with respect to fitting the housing enclosure structure 5 and the closure body 20 is however such that the housing enclosure structure 5 is already joined to the rest of the housing (directly to the motor space cover 4 in the example embodiment) before the closure body 20 is fitted, i.e. the closure body 20 is not attached to the housing enclosure structure 5 until after the housing enclosure structure 5 is fitted and sealing off the electronics space from the outside, aside from the housing opening 8.

FIG. 3 shows the closure body 20 itself, in an isometric view onto a lower side which faces the electronics space when the closure body 20 is fitted. The closure body 20 comprises a gas-tight and accordingly also liquid-tight, flat support body featuring a passage 21, and a gas-permeable but liquid-tight pressure equalization membrane 15 which is shown in FIG. 3 isolated from the support body. In the finished closure body 20, the pressure equalization membrane 15 is fastened to the support body, such that it covers the passage 21 and is connected to the support body in a liquid-tight seal circumferentially around the passage 21, for example by means of a glued or welded connection.

The closure body 20, more specifically its support body, exhibits a gasket structure 22 of the closure body 20, circumferentially around the passage 21, for joining it to the housing enclosure structure 5 in a liquid-tight and broadly gas-tight seal. The gasket structure 22 of the closure body 20 comprises an inner stay and an outer stay, each circumferentially around the passage 21 on the lower side of the closure body 20, between which a recess which is open towards the lower side is likewise delineated and circumferentially around the passage 21.

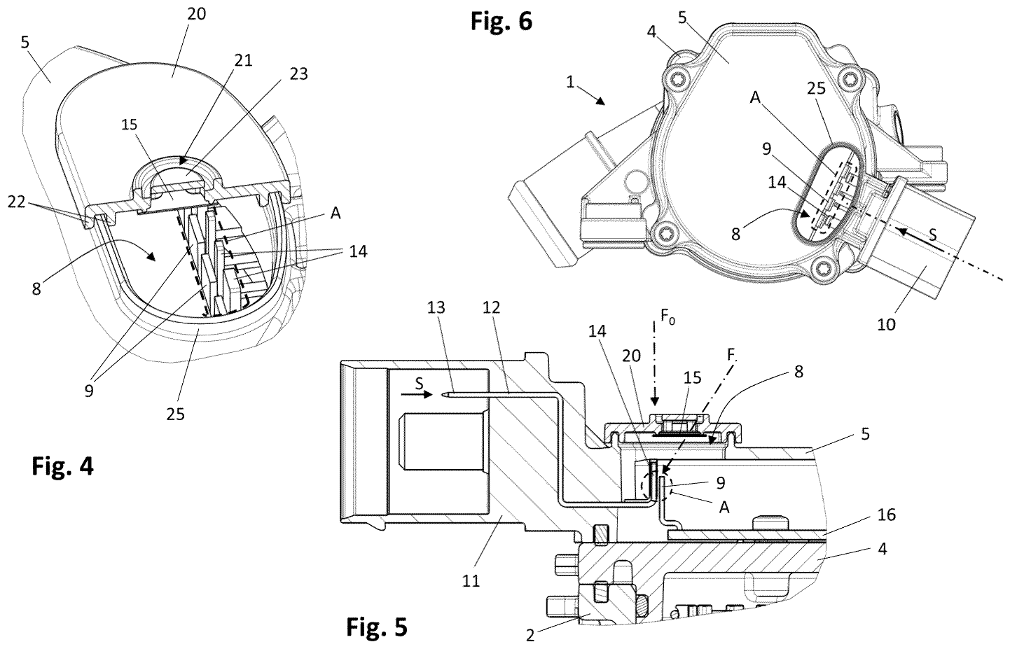

FIG. 4, like FIG. 2, shows only half of the closure body 20 and accordingly shows the housing opening 8 partially open and enlarged. Of the housing enclosure structure 5, only a wall region immediately adjoining the housing opening 8 and a gasket structure 25 of the housing 1 can be seen. The housing enclosure structure 5 abuts the rest of the housing, such that unlike in FIG. 3, the component part contacts 9 are located immediately opposite their assigned inner connector contacts 14. The component part contacts 9 and connector contacts 14 assigned to each other can be located opposite each other in pairs at a short distance or can directly abut each other in a loose pressure contact. The connecting region A, which is also indicated again, is formed by the component part contacts 9 and connector contacts 14 and, if an intermediate space remains between the individual pairs of contacts 9 and 14, also comprises said intermediate space.

The gasket structure 25 of the housing 1 protrudes upwards in the manner of a stay from the adjoining wall region of the housing enclosure structure 5 and, when the closure body 20 is joined, protrudes into the recess of the gasket structure 22 of the closure body 20.

The gasket structure 25 of the housing 1 encircles the housing opening 8. The inner stay and/or the outer stay of the gasket structure 22 of the closure body 20 can abut the gasket structure 25 of the housing 1 on the inside and/or outside when the closure body 20 is joined. When joined, the closure body 20 is connected in a material bond to the housing enclosure structure 5 in a seal, circumferentially around the housing opening 8, in the contact between the gasket structures 22 and 25. The gasket structures 22 and 25 thus also have a dual function as joining structures. The material-bond connection can in particular be a welded connection, for example a laser welded connection. The housing enclosure structure 5 and the closure body 20 are expediently formed from plastic materials which can be welded directly to each other. The housing enclosure structure 5 and the closure body 20 and/or its support body can in particular be formed from the same plastic.

The gasket structures 22 and 25 can also be designed with different geometries. The gasket structure 22 of the closure body 20 can then for example be provided with one stay only, and the gasket structure 25 of the housing 1 can alternatively (by reversing the conditions) be provided with two stays and a recess between them. The engagement itself would remain the same. It is in principle also possible for each of the two gasket structures 22 and 25 to exhibit only one stay for the purpose of joining in a seal.

It may also be added with respect to the closure body 20 that its support body exhibits an impact protection means 23 in the region of the passage 21, wherein the impact protection means 23 extends in front of the pressure equalization membrane 15 as viewed from the outside, in order to protect it from any inflowing particles.

FIG. 5 shows the housing enclosure structure 5 when fitted, wherein the housing enclosure structure 5 and the axially opposite motor space cover 4 delineate the electronics space comprising the electronic controller accommodated in it. Electronic component parts of the controller are not shown. All that is shown is the circuit board 16 on which the electronic component parts of the controller are arranged. One of the component part contacts 9, which respectively protrude next to each other from the circuit board 16 towards the housing opening 8 and the closure body 20, is also shown.

The longitudinal section of FIG. 5 extends through the connector 10. The connector 10 comprises a connector housing 11 and multiple electrical connecting lines 12, each comprising an outer connector contact 13 and an inner connector contact 14. One of these connecting lines 12 is shown in the longitudinal section of FIG. 5. The connecting lines 12 extend at a distance from each other in the connector housing 11. They are electrically isolated from each other. They can in particular be embedded in a plastic mass of the connector housing 11. They can be formed from flexible wires or more rigid rails, tapes or other initial shapes. The connecting lines 12 each extend through the connector housing 11 and terminate in the outer connector contacts 13 on an outer end-facing side of the connector 10 in order to form a connector port on said outer end-facing side. Their inner connector contacts 14 protrude into the interior space of the housing 1, where they terminate in the connecting region A. The outer connector contacts 13 protrude freely and linearly outwards, parallel to each other, counter to a plugging direction S in order to produce a plugging contact in each case. Alternatively, they could also be sleeve-shaped with a shared plugging direction S and form female connector contacts. The plugging direction S points normally and/or orthogonally with respect to the outer end-facing side of the connector 10.

The inner connector contacts 14 protrude freely into the electronics space (the interior space of the housing 1), where they each protrude towards the corresponding component part contact 9, wherein the inner connector contacts 14 each protrude up to and below the housing opening 8, as is preferred but in principle merely by way of example. The connecting region A is thus located in an orthogonal alignment Fₒ, which is indicated by a dashed arrow in FIG. 5, below the housing opening 8 in the electronics space.

The connector 10 protrudes outwards from a circumferential wall of the housing enclosure structure 5. The free inner end portions of the connecting lines 12 protrude from the circumferential wall of the housing enclosure structure 5 into the electronics space, towards the corresponding component part contacts 9. The protruding end portions of the connecting lines 12 bend sharply towards the housing opening 8, directly at the corresponding component part contacts 9, in order to overlap over a certain length with the component part contacts 9, which likewise protrude towards the housing opening 8, and to form an edge joint for the purpose of connecting.

In addition to the orthogonal alignment Fₒ, FIG. 5 also shows an oblique alignment F. The two alignments F and Fₒ shown illustrate that the connecting region A is accessible along a straight path, before the closure body 20 is fitted, via the housing opening 8 which is still open at this time, for example by a joining tool and/or a testing tool. A purely visual inspection through the housing opening 8 is equally possible, wherein the tool can be guided through the housing opening 8, vertically in accordance with the alignment Fₒ or obliquely in accordance with the alignment F, to the connecting region A. Before the closure body 20 is fitted, the corresponding pairs of component part contacts 9 and connector contacts 14 can thus be joined in an electrically conductive way by means of a joining tool, for example by means of a welded connection in each case.

The access to the connecting region obtained in this way can be used not only for joining the contacts 9 and 14, but additionally or alternatively also for testing or diagnostics. It is then for example possible to test whether the contacts are connected properly. It is also possible to perform diagnostics via one or more of the component part contacts, and in principle also at any other location outside the connecting region in the interior space of the housing which is accessible via the housing opening, of an electrical component part connected to them. The vehicle assembly can then exhibit one or more sensors, for example one or more Hall sensors for ascertaining the rotational speed and/or rotational angular position of the electric motor. With respect to the sensors, it is desirable to be able to perform diagnostics even when the vehicle assembly is being fitted and/or subsequently, for example in the event of a malfunction or within the framework of routine maintenance.

FIG. 6 shows the vehicle assembly in a plan view onto the housing enclosure structure 5, wherein said plan view is orthogonal with respect to the housing opening 8. The housing enclosure structure 5 is joined in a liquid-tight and broadly gas-tight seal to the rest of the housing (the motor space cover 4 in the example embodiment). The housing 1 is fully fitted aside from the closure body 20 and can be checked for strength of seal via the housing opening 8. For the purpose of testing, a pressure burden and/or a partial vacuum with respect to the environment is applied to the interior space of the housing 1 via the housing opening 8. If it is determined that the housing 1 has a sufficient seal, the housing opening 8 can be closed by the closure body 20. To this end, the closure body 20 is placed onto the housing enclosure structure 5 in the region of the housing opening 8, such that the joining gasket structures 22 and 25 (FIG. 4) engage with each other and can be connected to each other in a material bond, forming a circumferential seal.

In the plan view of FIG. 6, all of the component part contacts 9 and connector contacts 14 and therefore the entire connecting region A is/are visible through the housing opening 8 which is still open. All of the component part contacts 9 and connector contacts 14 which are to be connected to each other in an electrically conductive way are accessible along a straight path through the housing opening 8. They can therefore advantageously be connected once the housing enclosure structure 5 has been fitted. Fitting the housing enclosure structure 5 also simultaneously positions the inner connector contacts 14 relative to the corresponding component part contacts 9 in the connecting region A, such that the contacts 9 and 14 can be connected in an electrically conductive way by a joining process immediately after the housing enclosure structure 5 has been fitted. The strength-of-seal test is expediently performed after the contacts have been connected.

The component part contacts 9 and the connector 10 are arranged close to each other, such that the inner connector contacts 14 only have to protrude into the interior space of the housing 1 by a correspondingly small length. The housing opening 8 advantageously opens into the same half of the interior space of the housing 1 as the connector contacts 14 of the connecting lines 12 protrude into. The component part contacts 9 and accordingly the connecting region A can be arranged immediately behind the connector 10 in the plugging direction S. The housing opening 8 can advantageously likewise be arranged immediately behind the connector 10 in the plugging direction S and preferably in an overlap with the connecting region A as viewed in a plan view.

The connecting region A is elongated along a connecting line which connects the contact points of the component part contacts 9 and connector contacts 14. The housing opening 8 can be formed in accordance with the dimensions of the connecting region A and can exhibit a length along the connecting line which is greater than the width as measured transversely to it. The connecting region A and, in accordance with it, the housing opening 8 can then each exhibit a maximum extent transversely with respect to the plugging direction S.

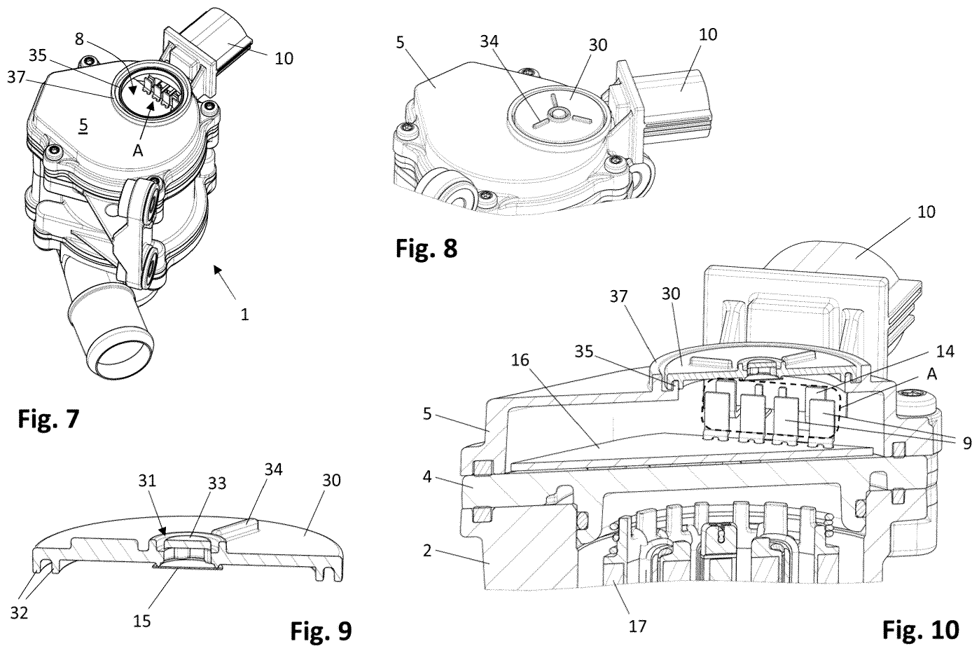

In a second example embodiment shown in FIGS. 7 to 12, the vehicle assembly exhibits a housing 1 which differs from the housing 1 of the first example embodiment only with respect to the housing opening 8 and the correspondingly adapted closure body 30. The vehicle assembly and in particular its housing 1 otherwise correspond to the first example embodiment.

In the second example embodiment, the housing opening 8 is circular as viewed in a plan view and is encircled by a circular gasket structure 35 of the housing 1. The gasket structure 35 of the housing 1, like the gasket structure 25 of the housing 1 of the first example embodiment, protrudes upwards from the adjoining wall region of the housing enclosure structure 5 in the form of a short stay, as shown in the overall isometric view of FIGS. 7 and the sectional isometric view of FIG. 10.

In accordance with the gasket structure 35 of the housing 1, the lower side of the closure body 30 exhibits a likewise circular gasket structure 32 of the closure body 30 which, as in the first example embodiment, is formed by two stays protruding downwards on the support body and a recess remaining between the stays. The shape of the gasket structures 32 and 35, which is circular as viewed in the respective plan view, enables the closure body 30 to be joined in a gas-tight seal to the housing enclosure structure 5 by spin welding. The closure body 30 is expediently likewise circular over its peripheral edge, although this is not absolutely necessary.

In order to facilitate spin welding, the upper side of the closure body 30 which points outwards when the housing 1 is fully fitted is provided with multiple joining aids 34 which a joining tool for spin welding can engage in order to introduce a torque. The joining aids 34 are formed as rib-shaped protrusions. The closure body 30 otherwise corresponds to the closure body 20 of the first example embodiment and accordingly exhibits a passage 31, the gas-permeable but liquid-tight pressure equalization element 15 and, in front of the pressure equalization element 15 in the inflow direction, an impact protection means 33 in the central region.

The joining region of the motor housing 2 and motor space cover 4 and the joining region of the motor space cover 4 and housing enclosure structure 5 are shown in the sectional isometric view of FIG. 10. A stator 17 of the electric motor accommodated in the motor space is also shown, which extends up to the vicinity of the motor space cover 4. FIG. 10 exposes the electronics space which is delineated on an inner end-facing side by the motor space cover 4 and on an outer end-facing side by the housing enclosure structure 5 which also delineates the electronics space circumferentially.

As already described with respect to the first example embodiment, the component part contacts 9 and inner connector contacts 14 which are connected in an electrically conductive way define the connecting region A. As in the first example embodiment, the connecting region A is completely aligned orthogonally with respect to the housing opening 8 and is therefore completely overlapped by the housing opening 8 as viewed in an orthogonal plan view onto the housing opening 8, such that the connecting region A is located completely within the circumferential edge of the housing opening 8 as viewed in this plan view. Positioning and dimensioning the housing opening 8 in this way enables the best possible access to the connecting region A, i.e. unhindered access aside from the edging of the housing opening 8.

The housing enclosure structure 5 of the second example embodiment is developed for the purpose of easily docking a testing tool for a strength-of-seal test on the housing 1. For this purpose, it exhibits a docking ring 37 which encircles the gasket structure 35 of the housing 1 and protrudes outwards from the adjoining wall region of the housing enclosure structure 5 in a comparable way to the gasket structure 35 of the housing 1. When the closure body 30 is fitted, the docking ring 37 also surrounds the closure body 30 and terminates flush with a planar outer end-facing area of the closure body 30. Expediently, the free upper sides of the closure body 30 and docking ring 37 jointly form a docking plane on which a testing tool can dock in a sealing contact in a particularly easy way.

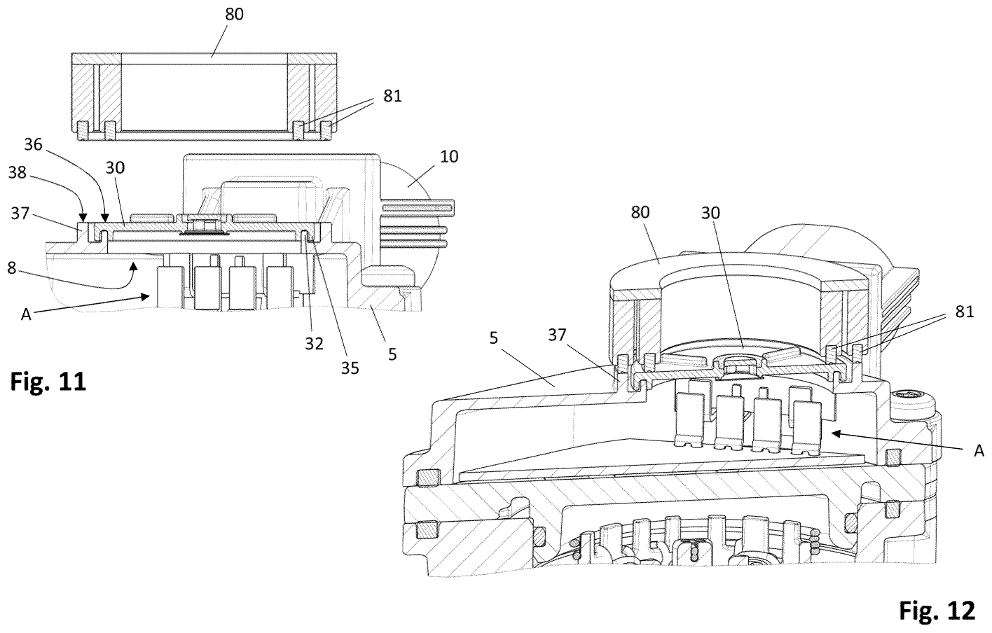

FIG. 11 shows a longitudinal section of the housing enclosure structure 5 in the region of the housing opening 8 and the connecting area A which overlaps with it, together with a testing probe 80 of a testing tool for a strength-of-seal test. The closure body 30 is fitted. The testing probe 80 is positioned at a short axial distance above the closure body 30 for docking in order to perform a strength-of-seal test on the joining connection between the housing enclosure structure 5 and the closure body 30. Before the closure body 30 was fitted, the strength of seal on the housing as a whole was checked using the same testing probe 80, by docking the testing probe 80 on the docking ring 37 while the housing opening 8 was still open and applying a pressure burden and/or a partial vacuum relative to the environment to the housing via the testing probe 80. Following this main strength-of-seal test, the closure body 30 was fitted such that in the next step, a subsequent strength-of-seal test can be performed on the joining connection between the closure body 30 and the housing enclosure structure 5.

The lower side of the testing probe 80 facing the housing enclosure structure 5 exhibits two circumferential axial gaskets 81 in the form of an inner gasket ring and an outer gasket ring which surrounds the inner gasket ring. For the purpose of performing the strength-of-seal test on the housing while the housing opening 8 is still open, the outer gasket ring 81 of the testing probe 80 is pressed against a docking area 38 of the docking ring 37 facing it, in order to circumferentially seal the housing opening 8 in a gas-tight seal at the docking area 38. The docking area 38 is a free upper end-facing area of the docking ring 37.

FIG. 12 shows the testing probe 80 when docked for a second and final strength-of-seal test, i.e. with the housing opening 8 closed. For the purpose of performing the second strength-of-seal test, the inner gasket ring 81 of the testing probe 80 is pressed against a docking area 36 of the closure body 30, wherein its outer gasket ring 81 is simultaneously pressed against the docking area 38 of the docking ring 37 again. A pressure burden and/or partial vacuum is then applied to an annular gap which remains circumferentially between the closure body 30 and the docking ring 37 by the testing probe 80, when the testing probe 80 is docked. The strength of seal on the joining connection between the housing enclosure structure 5 and the closure body 30 is thus tested via the annular gap which remains free. The docking area 36 of the closure body 30 surrounds the passage 31 and is surrounded by the docking area 38 of the docking ring 37. The two docking areas 36 and 38 form a shared docking plane, such that a geometrically simple, typical testing probe 80 can be used.

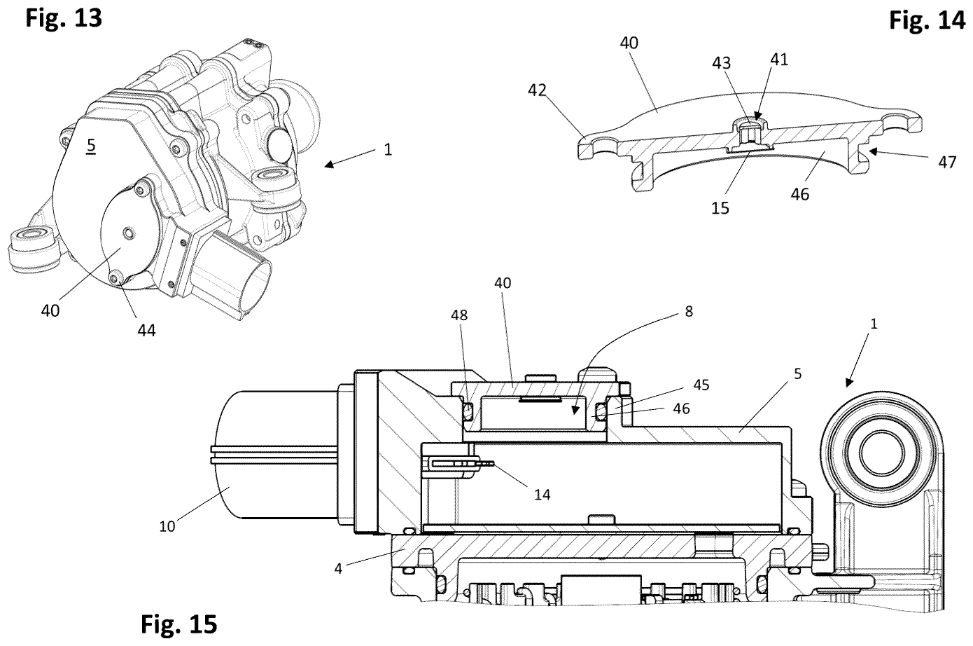

FIGS. 13 to 15 show a vehicle assembly comprising a housing 1 which exhibits a housing enclosure structure 5 and a closure body 40 of a third example embodiment. Unlike the closure bodies 20 and 30, the closure body 40 is not joined to the housing enclosure structure 5 in a material bond, but rather in a frictional fit, for example by means of a screw connection. FIG. 13 shows fastening elements 44, for example in the form of screw fastening elements, wherein the closure body 40 is fastened by two fastening elements 44, likewise merely by way of example. The closure body 40 is pressed against the housing enclosure structure 5 by means of the fastening elements 44.

FIG. 14 shows the closure body 40 individually, in a sectional isometric view. The closure body 40 corresponds to the closure bodies of the first and second example embodiments with respect to the passage 41, the pressure equalization membrane 15 and the impact protection means 43. Instead of the joining structures 22 and 32, which are designed to produce a welded connecting seam, the joining structure 42 of the closure body 40 can be a circumferential flange comprising passages for the fastening elements 44 or, as in the example embodiment, multiple fastening flanges which protrude outwards in the manner of vanes from a disc-shaped central region of the closure body 40 and each have a passage running through them for one of the fastening elements 44.

A gasket structure 46 in the form of a stay protrudes on the lower side from the disc-shaped region of the closure body 40. The gasket structure 46 encircles the passage 41 between the passage 41 and the joining structure 42. The outer circumference of the gasket structure 46 circumferentially exhibits a receptacle 47 for a gasket element. The receptacle 47 is formed as a groove-shaped recess on the outer circumference of the gasket structure 46.

FIG. 15 shows the housing enclosure structure 5 and the region of the housing 1 adjoining it, in a longitudinal section which extends through the housing opening 8 and the closure body 40. As in the first and second example embodiments, the connecting region is aligned, preferably orthogonally, with the housing opening 8. However, only the inner connector contacts 14 and not the component part contacts are shown.

The housing enclosure structure 5 exhibits a gasket structure 45 of the housing 1 for joining it in a gas-tight seal to the closure body 40, wherein (as in the first and second example embodiments) the gasket structure 45 of the housing 1 encircles the housing opening 8, where it protrudes outwards from an adjoining wall region of the housing enclosure structure 5, forming a stay. When the closure body 40 is fitted, the gasket structure 46 of the closure body 40 protrudes into the housing opening 8 encircled by the gasket structure 45 of the housing 1, such that the outer circumferential area of the gasket structure 46 of the closure body 40 and an inner circumferential area of the gasket structure 45 of the housing 1 circumferentially form a sealing gap with each other. The sealing gap is sealed off in a gas-tight seal by an annular gasket element 48. The gasket element 48 is accommodated in the receptacle 47 (FIG. 14) of the closure body 40. The gasket element 48 acts as a radial gasket in the sealing gap. The gasket structure 45 of the housing 1 protrudes sufficiently far from the adjoining wall region of the housing enclosure structure 5 to circumferentially ensure the sealing contact with the gasket element 48.

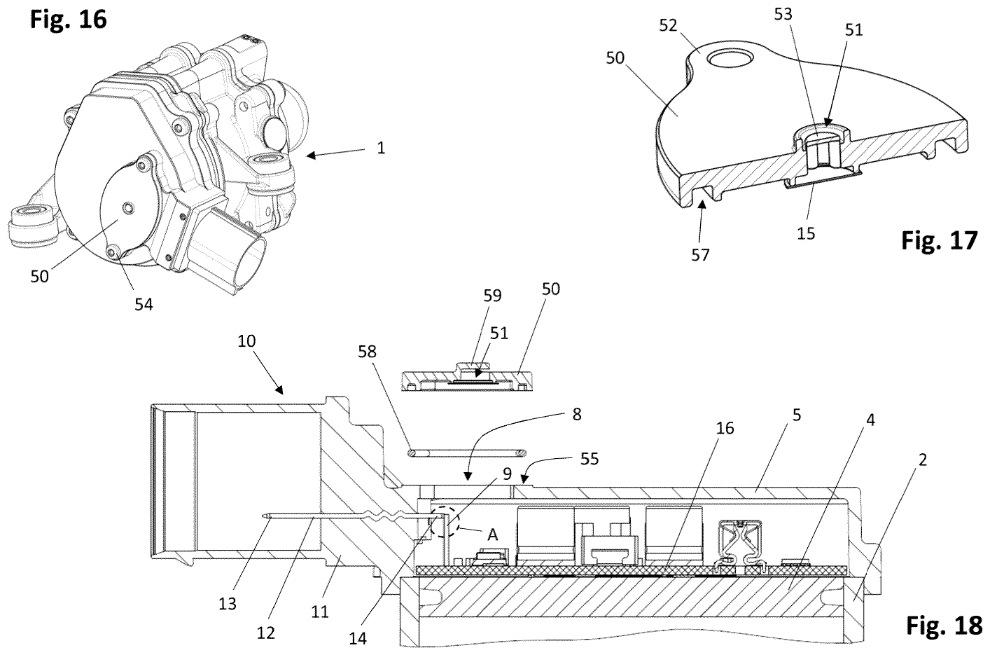

FIGS. 16 to 18 show a vehicle assembly comprising a housing 1 which exhibits a housing enclosure structure 5 and a closure body 50 of a fourth example embodiment. As in the third example embodiment, the closure body 50 is joined to the housing enclosure structure 5 in a frictional fit, for example again in the form of a screw connection using multiple fastening elements 54. For this purpose, the closure body 50 exhibits a joining structure 52 which can be formed as a circumferential fastening flange or, as in the example embodiment, by multiple fastening flanges which protrude in the manner of vanes, wherein the respective fastening flange has a passage running through it for one of the fastening elements 54. The respective fastening element 54 can in particular again be a fastening screw. The fourth example embodiment can correspond to the third example embodiment with respect to how it is fastened to the housing enclosure structure 5. The closure body 50 shown in FIG. 16 and in detail in FIG. 17 corresponds to the closure bodies of the previous example embodiments with regard to the passage 51, the pressure equalization membrane 15 and the impact protection means 53.

With regard to sealing off the housing opening 8, the closure body 50 corresponds in principle to the third example embodiment, in that the housing opening 8 is sealed off by means of an annular gasket element 58 (FIG. 18). The lower side of the substantially disc-shaped closure body 50 exhibits a protruding inner stay and a protruding outer stay which encircle the central passage 51 between the passage 51 and the joining structure 52, wherein a recess is circumferentially formed between the inner and outer stays as a receptacle for the gasket element 58. Together with the receptacle, the stays form the gasket structure 57 of the closure body 50. In one modification, the gasket structure 57 can also be implemented as a groove-shaped recess directly in the end-facing area of the closure body 50, without the raised stays.

When the closure body 50 is fitted, the gasket element 58 is pressed against a free end-facing area of the housing enclosure structure 5, wherein it acts as an axial gasket which seals off a sealing gap between the housing enclosure structure 5 and the closure body 50, circumferentially around the housing opening 8, in a gas-tight seal. The end-facing area of the housing enclosure structure 5, which the gasket element 58 abuts when joined, can be exposed in order to facilitate processing. For this purpose, and as shown in FIG. 18, the housing enclosure structure 5 exhibits a gasket structure 55 in the form of a flat projection, the end-facing area of which forms the abutting area for the gasket element 58. Implementing the joining structure 55 as a flat projection improves access to the connecting region A as compared to a housing opening 8 which protrudes further outwards, as is for example provided in the third example embodiment.

FIG. 18 shows a closure body 50 which has been modified with regard to the impact protection means for the pressure equalization membrane 15. Instead of the impact protection means 53 of FIG. 17, which is formed in the passage 51 in a recessed position, a modified impact protection means 59 protrudes outwards on the outer side of the closure body 50. It is connected to the disc-shaped region of the closure body 50 via a crimped portion on one side (integrally formed in the example embodiment) and protrudes outwards slightly beyond the disc-shaped region, such that a narrow gap through which fluid can flow for equalizing the pressure remains over most of the circumference of the passage 51.

It is indicated in FIG. 18 that the inner connector contacts 14 simply protrude linearly into the interior space of the housing, and only their ends on the end-facing side are joined to the component part contacts 9 in the connecting region A and can thus be connected.

Aside from the differences described, the third and fourth example embodiments correspond to the first example embodiment.

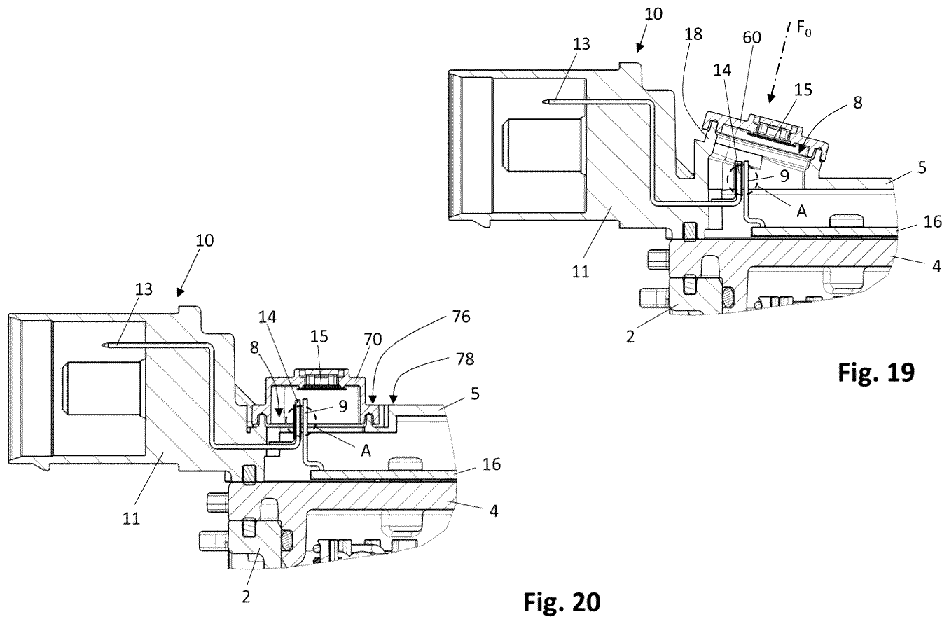

FIG. 19 shows a detail of a vehicle assembly comprising a housing enclosure structure 5 of a fifth example embodiment. The fifth example embodiment differs from the first example embodiment with respect to the housing opening 8 and the arrangement of the component part contacts 9 and connector contacts 14.

In the fifth example embodiment, the housing opening 8 is inclined away from the electrical connector 10 relative to the motor space cover 4 located opposite on the end-facing side at an angle of inclination of preferably at least 10° and preferably at most 40°. The alignment Fₒ which is orthogonal with respect to the housing opening 8 is correspondingly inclined. In order to position the housing opening 8 obliquely, the housing enclosure structure 5 exhibits an edging 18, circumferentially around the housing opening 8, which protrudes further on its side close to the connector 10 than on its side away from the connector 10. The housing opening 8 which is thus obtained at the front-facing end of the edging 18 corresponds in terms of its cross-section to the first example embodiment. The front portion of the edging 18 which extends as far as the front-facing end circumferentially forms a gasket structure which corresponds to the gasket structure 25 of the housing 1 of the first example embodiment and which again simultaneously performs the function of a joining structure. The closure body of the first example embodiment is used as the closure body 60. Positioning the housing opening 8 obliquely can in particular be advantageous for access to the connecting region A when the electrical connector 10 is provided close to the housing opening 8, as is preferred, and protrudes beyond the housing opening 8.

The second modification is that the component part contacts 9 and connector contacts 14 extend up to and into the edging 18 of the housing opening 8, such that the connecting region A is at least substantially formed within the edging 18. This also helps to improve access to the connecting region A. Aside from the two differences described, the fifth example embodiment corresponds to the first example embodiment.

FIG. 20 shows a sixth example embodiment in which a closure body 70 is used which not only caps the housing opening 9 but simultaneously also surrounds a larger part of the connecting region A or, as in the example embodiment, all of the connecting region A. The closure body 70 is thus a closure cap. The joining connection to the housing enclosure structure 5, including the seal which it also provides, corresponds to the first or second example embodiment, as already demonstrated in FIG. 20.

In the sixth example embodiment, the component part contacts 9 and connector contacts 14 are extended outwards beyond the housing opening 8 and even protrude slightly beyond the housing enclosure structure 5 on the outer end-facing side of the housing enclosure structure 5. The connecting region A is therefore particularly easy to access when the housing opening 8 has not yet been closed. The connecting region A is therefore aligned, even orthogonally, with the housing opening 8, only now in front of the housing opening 8 and/or in the housing opening 8 as viewed from the outside, such that a tool for joining or testing does not have to be guided into the interior space of the housing through the opening.

The housing opening 8 extends in a wall region of the housing enclosure structure 5 which is lowered around the connecting region A. Lowering the wall region at least partially exposes the contacts 9 and 14 and the connecting region A. In modifications, it is also possible for only the contacts 9 and 14 to be extended and for lowering the wall region to be omitted. In modifications of the other example embodiments, the contacts 9 and 14 can then protrude freely beyond the respective housing opening 8, wherein a cap-shaped closure body could then be respectively used in a comparable way to the closure body 70, in order to close the respective housing opening 8.

FIG. 20 also shows how the housing enclosure structure 5 and the closure body 70 are adjusted to each other for docking a testing probe for a strength-of-seal test. They are adjusted to each other in that the outer side of the closure body 70 exhibits a planar docking area 76, circumferentially around its passage which is closed by the pressure equalization element 15, on the end-facing side and the housing enclosure structure 5 exhibits a planar docking area 78, circumferentially around the docking area 76, on the end-facing side and the docking areas 76 and 78 extend in a shared docking plane and are separated by an annular gap. It is then possible to perform a first strength-of-seal test before the closure body 70 is attached, and a second strength-of-seal test after the closure body 70 has been attached, using the testing probe 80 (FIGS. 11 and 12), as described with respect to the second example embodiment.

REFERENCE SIGNS
1 housing
2 motor housing, housing support structure
3 pump space cover
4 motor space cover, housing support structure
5 housing enclosure structure, electronics space cover
6 inlet
7 outlet
8 housing opening
9 component part contact
10 connector
11 connector housing
12 connecting line
13 outer connector contact
14 inner connector contact
15 pressure equalization element
16 electrical component part, controller
17 electrical component part, stator
18 edging
19 -
20 closure body
21 passage
22 gasket structure, joining structure
23 impact protection means
24 -
25 gasket structure, joining structure
26 -
27 -
28 -
29 -
30 closure body
31 passage
32 gasket structure, joining structure
33 impact protection means
34 joining aid
35 gasket structure, joining structure
36 docking area
37 docking ring
38 docking area
39 -
40 closure body
41 passage
42 joining structure
43 impact protection means
44 fastening element
45 gasket structure
46 gasket structure, stay
47 gasket structure, receptacle
48 gasket element
49 -
50 closure body
51 passage
52 joining structure
53 impact protection means
54 fastening element
55 gasket structure, joining structure
56 -
57 gasket structure, recess
58 gasket element
59 impact protection means
60 closure body
70 closure body
76 docking area
78 docking area
80 testing probe
81 gasket
A connecting region
F alignment
Fₒ orthogonal alignment

1. A vehicle assembly comprising:
a housing comprising a housing enclosure structure which delineates an interior space of the housing circumferentially and/or on an end-facing side and exhibits a housing opening;
an electrical component part accommodated in the housing;
an electrical connector comprising an electrically conductive outer connector contact, for electrically connecting the vehicle assembly to an electrical system of a vehicle, and an electrically conductive inner connector contact;
a component part contact which is connected in an electrically conductive way to the electrical component part and joined in an electrically conductive way to the inner connector contact in a connecting region;
a closure body for closing the housing opening against the ingression of liquid; and
a gas-permeable pressure equalization element which is a constituent part of the closure body, in order to enable pressure to be equalized with the environment of the housing via the closure body,
wherein the housing opening, when it is not closed, enables the connecting region to be accessed by a tool and/or enables a visual inspection of the connecting region.

2. The vehicle assembly according to claim 1, wherein the housing opening is in alignment with the connecting region and, when it is not closed, enables the connecting region to be accessed by a tool and/or enables a visual inspection of the connecting region along a straight path.

3. The vehicle assembly according to claim 1, wherein the housing opening as viewed in a plan view overlaps at least predominantly with the connecting region, preferably the component part contact and/or the inner connector contact, over an area.

4. The vehicle assembly according to claim 1, wherein the housing comprises a housing support structure, which mounts the electric motor and/or the electronic controller, and a housing cover which is joined to the housing support structure, wherein the housing support structure and the housing cover jointly surround an interior space of the housing in which the respective electrical component part is accommodated and/or in which the connecting region is located, and wherein the housing cover is the enclosure structure comprising the housing opening.

5. The vehicle assembly according to claim 1, wherein the housing enclosure structure and the electrical connector form a fitted unit, and the electrical connector comprises a connector housing and an electrical connecting line which extends through the connector housing into the interior space of the housing and forms the outer connector contact and the inner connector contact, wherein the connector housing holds the connecting line and positions it relative to the housing opening, preferably such that the inner connector contact is in an alignment which extends through the housing opening.

6. The vehicle assembly according to claim 1, wherein
the vehicle assembly can be connected to the electrical system of the vehicle on an end-facing side of the electrical connector,
an axis which is central with respect to the connector and extends orthogonally with respect to the end-facing side of the connector intersects the housing opening as viewed in a plan view onto the housing opening,
and the housing opening is arranged close to the connector as viewed in the plan view onto the housing opening, in a half of the housing enclosure structure into which the inner connector contact protrudes.

7. The vehicle assembly according to claim 1, wherein the closure body comprises a passage, which the pressure equalization element closes in a liquid-tight seal, and a gasket structure which surrounds the passage in order to seal off the housing opening in a liquid-tight and preferably gas-tight seal, circumferentially around the housing opening or in the housing opening as viewed in a plan view.

8. The vehicle assembly according to claim 1, wherein the closure body is joined to the housing in a material bond along a joining area or line, in a liquid-tight and preferably gas-tight seal, circumferentially around the housing opening, preferably by welding, or wherein the closure body is joined to the housing in a liquid-tight and preferably gas-tight seal by means of a gasket element and a screw connection or locking connection.

9. The vehicle assembly according to claim 1, wherein the closure body is joined to the housing in a gas-tight seal circumferentially around the housing opening, and wherein the housing exhibits a free docking area, circumferentially around the closure body as viewed in a plan view, for a circumferentially gas-tight contact with a testing probe for determining the strength of seal on the housing and/or the joining connection between the closure body and the housing by means of a pressure-burden and/or partial-vacuum strength-of-seal test.

10. The vehicle assembly according to claim 9, wherein the closure body exhibits a passage, which the pressure equalization element closes in a liquid-tight seal, and a free docking area circumferentially around the passage for a circumferentially gas-tight contact with the testing probe.

11. The vehicle assembly according to claim 10, wherein the docking areas are planar parallel end-facing areas which preferably extend in a shared docking plane.

12. The vehicle assembly according to claim 1, wherein the vehicle assembly is a pump-motor unit, and an impeller for delivering fluid, an electric motor for rotationally driving the impeller and an electronic controller for the electric motor are arranged in the housing.

13. A method for fitting a vehicle assembly according to claim 1, the vehicle assembly comprising:
a housing comprising an enclosure structure which delineates an interior space of the housing circumferentially and/or on an end-facing side and exhibits a housing opening;
an electrical component part, for example an electric motor or an electronic controller, accommodated in the housing;
an electrical connector comprising an outer connector contact, for electrically connecting the vehicle assembly to an electrical system of a vehicle, and an inner connector contact;
a component part contact which is connected in an electrically conductive way to the electrical component part and is adjacent to the inner connector contact in a connecting region;
a closure body for closing the housing opening against the ingression of liquid; and
a gas-permeable pressure equalization element which is a constituent part of the closure body, in order to enable pressure to be equalized with the environment of the housing via the closure body,
wherein the inner connector contact is joined in an electrically conductive way to the component part contact by means of a joining tool before the housing opening is closed,
and wherein the housing opening is closed in a liquid-tight but gas-permeable seal by the closure body.

14. The method according to claim 13, wherein
the connecting region is formed in the interior space of the housing, the joining tool is guided to the connecting region through the housing opening which is still open, and the contacts are joined in an electrically conductive way, or
the component part contact and the inner connector contact protrude outwards through the housing opening and are joined in the connecting region on the outside, in front of the housing opening, in an electrically conductive way, and a cap-shaped closure body is used to close the housing opening.

15. The method according to claim 13, wherein the housing enclosure structure forms a fitted unit with the connector and is joined to a housing support structure, which mounts the electrical component part, and the inner connector contact is positioned for being joined in an electrically conductive way by joining the housing enclosure structure in the connecting region.

16. The method according to claim 14, wherein the housing enclosure structure forms a fitted unit with the connector and is joined to a housing support structure, which mounts the electrical component part, and the inner connector contact is positioned for being joined in an electrically conductive way by joining the housing enclosure structure in the connecting region.
